(19) United States
(12) Patent Application Publication
(10) Pub. No.: US 2009/0117496 A1
(43) Pub. Date: May 7, 2009

(54) METHOD FOR TREATING SURFACE OF ELEMENT

(76) Inventors: Tsung-Ting Yuan, Taipei County (TW); Cheng-Chang Lee, Yunlin County (TW); Heng-Chung Chang, Taichung City (TW); Huang-Kun Chen, Taoyuan City (TW); Tai-Kang Shing, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/171,299

(22) Filed: Jul. 11, 2008

(30) Foreign Application Priority Data
Nov. 2, 2007 (TW) 096141535

(51) Int. Cl. G03F 7/20

(52) U.S. Cl. 430/323; 430/322; 430/325; 430/324; 430/326

(57) ABSTRACT

A method for treating a surface of an element includes the steps of providing a photo-sensitive and flexible thin film, providing a planar photomask having a micro-structural pattern, transferring the micro-structural pattern to the thin film, attaching the thin film to the surface of the element and partially exposing a portion of the element, processing the exposed portion of the element, and removing the thin film to form a micro-structure on the surface of the element.

### BACKGROUND OF THE INVENTION

1. Field of the Invention

The present invention relates to a method for treating the surface of an element, and more particularly, to a method using a photo-sensitive and flexible thin film to transfer a micro-structural pattern to an element having a non-planar surface.

2. Description of the Prior Art

The surface treatment of non-planar element is difficult due to its non-planar surface and the trend of miniaturization. Taking a fluid dynamic bearing as an example, the inner wall of the bearing has minute grooves with lubricant filled therein. When a shaft of a motor rotates, the lubricant filled in the grooves of the bearing will be drawn and spread all over the surface of the shaft, thereby generating a dynamic pressure. This dynamic pressure maintains the shaft in a central position of the bearing, and thus prevents friction between the shaft and the inner wall of the bearing, and restrains noises.

However, the inner wall of the bearing is a curved surface so that to form the groove disposed thereon is difficult. The grooves to be formed have extremely minute width and depth, which makes it difficult to control the accuracy. Currently, several manufacturing techniques have been proposed, such as cutting technique, rolling technique, plastic injection technique, assembling technique and machining technique after thin film process. The methods, nevertheless, are costly because each of the methods requires particular machining tools, and have some disadvantages. For example, the turning section of the grooves formed by cutter technique is sometimes discontinuous, and the depth and width of the grooves are not identical. In addition, the problems such as the expensive cost of machining equipment, the fragility of cutter, the incapability of mass production, the low tolerance of vibration of the machining environment, and the requirement of professional worker, etc, are the difficulties that the conventional fluid dynamic bearing fabrication method have to overcome.

### SUMMARY OF THE INVENTION

It is therefore one of the objectives of the present invention to provide a method for treating a surface of an element to improve the high cost and inconsistent quality problems of the conventional surface treatment.

According to the present invention, a method for treating a surface of an element includes steps of: providing a photo-sensitive and flexible thin film; providing a planar photomask having a micro-structural pattern; transferring the micro-structural pattern to the thin film; providing an element having a non-planar surface; attaching the thin film having the micro-structural pattern to the non-planar surface of the element. The thin film partially exposes the non-planar surface of the element, thereby forming at least an exposed region on the non-planar surface of the element. Subsequently, at least a material layer is disposed on the thin film and on the exposed region of the non-planar surface of the element by performing a coating process. Then, the thin film and the material layer formed on the thin film are removed to form a micro-structure on the non-planar surface of the element.

According to the present invention, a method for treating a surface of an element includes steps of: providing a photo-sensitive and flexible thin film; providing a planar photomask having a micro-structural pattern; transferring the micro-structural pattern to the thin film; providing an element having non-planar surface; attaching the thin film having the micro-structural pattern to the non-planar surface of the element. The thin film partially exposes the surface of the element, thereby forming at least an exposed region on the surface of the element. Subsequently, the exposed region of the element is etched by performing an etching process, and the thin film is then removed to form a micro-structure on the non-planar surface of the element.

According to the present invention, a method for treating a surface of an element includes steps of: providing a photo-sensitive and flexible thin film; providing a planar photomask having a micro-structural pattern; transferring the micro-structural pattern to the thin film; and attaching the thin film having the micro-structural pattern to a non-planar surface of the element. The thin film partially exposes the non-planar surface of the element, thereby forming at least an exposed region on the surface of the element. Subsequently, the exposed region of the non-planar surface of the element is treated by performing a surface treatment, and the thin film is removed to form a micro-structure on the non-planar surface of the element.

The present invention uses a photo-sensitive, flexible and adhesive thin film to form a micro-structure on the non-planar surface of the element. The thin film is exposed in advance so that a micro-structural pattern is transferred from a planar photomask to the thin film, and the thin film is then attached to the non-planar surface of the element. The surface treatment such as an electroplating process or an etching process is implemented by virtue of the thin film with the micro-structural pattern.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIGS. 1-6 are schematic diagrams illustrating steps of a method for treating an element having a non-planar surface according to the first embodiment of the present invention.

FIGS. 7 and 8 are schematic diagrams illustrating steps of a method for treating an element having a non-planar surface according to the second embodiment of the present invention.

### DETAILED DESCRIPTION

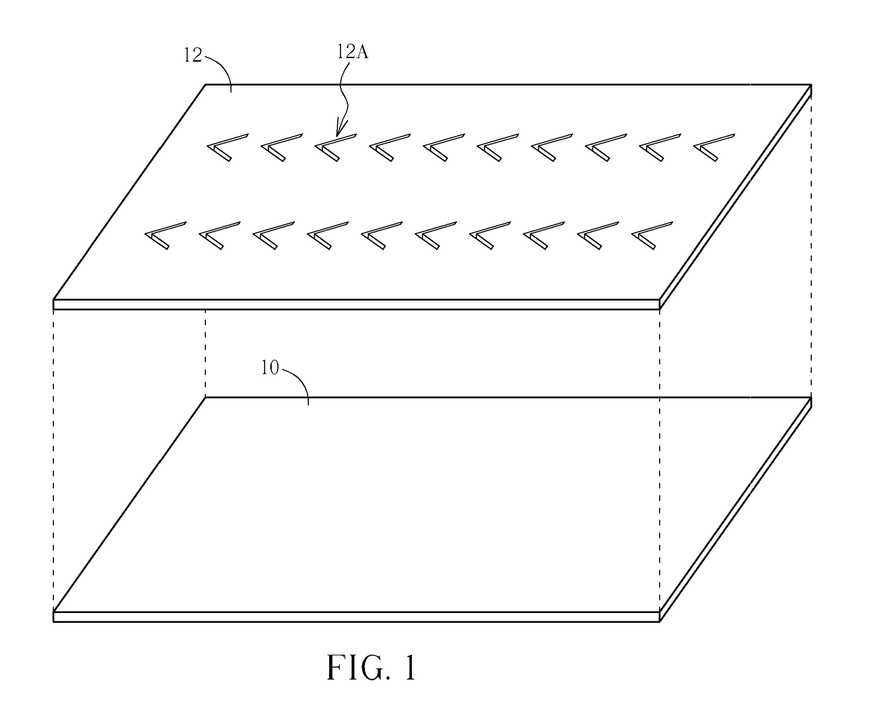

FIGS. 1-6 are schematic diagrams illustrating steps of a method for treating an element having a non-planar surface according to the first embodiment of the present invention. As shown in FIG. 1, a thin film 10, which is photo-sensitive, flexible and easy to attach, is provided, wherein the material of the thin film 10 may be various kinds of photoresist e.g. positive type, negative type, single-layered or multi-layered photoresist. Subsequently, a planar photomask 12 having a micro-structural pattern 12A to be formed on an element having a non-planar surface is provided.

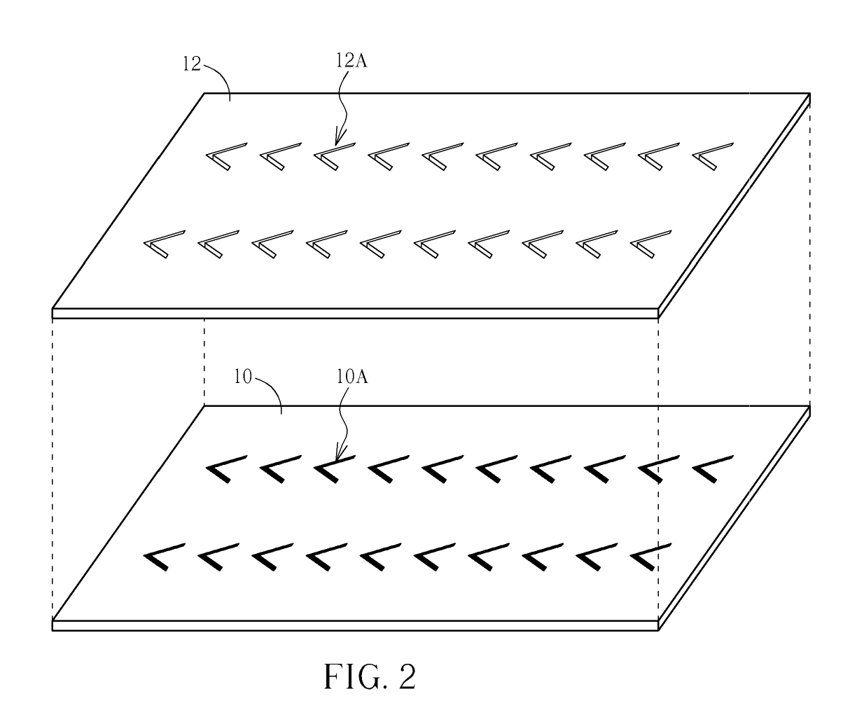

As shown in FIG. 2, an exposure process is subsequently carried out to transfer the micro-structural pattern 12A to the thin film 10 so that a micro-structural pattern 10A corresponding to the micro-structural pattern 12A is formed on the thin film 10. Please note the micro-structural pattern 12A of the planar photomask 12 must be consistent with the material of the thin film 10. For instance, if the thin film 10 is positive type photoresist, the micro-structural pattern 12A of the planar photomask 12 should be identical to the pattern of the thin film 10 after developed. On the other hand, if negative type photoresist is selected as the material of the thin film 10, the micro-structural pattern 12A of the planar photomask 12 and the pattern of the thin film 10 after developed should be complementary to each other.

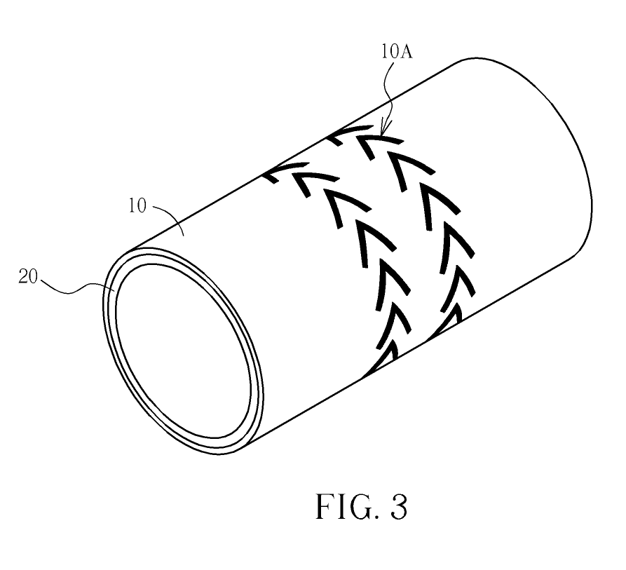

As shown in FIG. 3, an element 20 is provided. The material of the element 20 may be metal such as copper or non-metal such as glass. Then, the thin film 10 having the micro-structural pattern 10A formed thereon is attached tightly to the curved surface of the element 20. In the instant embodiment, a cylindrical tubal structured element is selected to illustrate the characteristic of the present invention, however, the method of the present invention is not limited and can be used to various types of non-planar surface treatment.

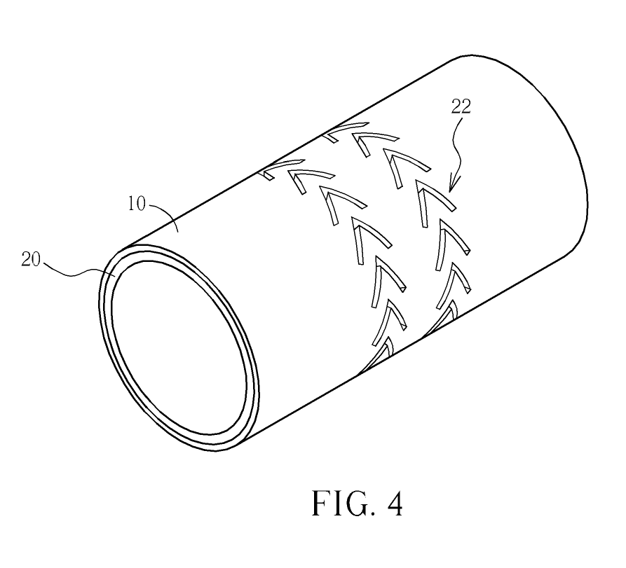

As shown in FIG. 4, a development process is performed upon the thin film 10 to remove the unexposed portion of the thin film 10. Accordingly, the thin film 10 partially exposes the curved surface of the element 20, thereby forming at least one exposed region 22 on the surface.

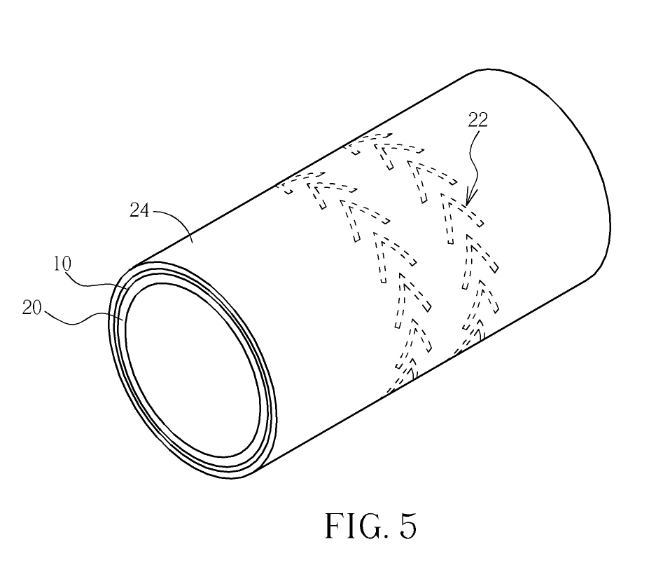

As shown in FIG. 5, a coating process is implemented to form at least a material layer 24 on the thin film 10 and on the exposed region 22 of the surface of the element 20 as well. The coating process may be various kinds of processes based on different material of the material layer 24 formed on the thin film 10. For instance, the coating process can be a physical vapor deposition (PVD) process, a chemical vapor deposition (CVD) process, evaporation process, sputtering process, electroplating process, and non-electroplating process, etc. In addition, the material of the material layer 24 can be metal, nonmetal, oxide or a mixture of the aforementioned materials based on the micro-structure to be formed. The material layer 24 is not limited to single-layered, and may be multi-layered. It is appreciated that the material layer 24 shown in FIG. 5 thoroughly covers the exposed region 22 of the element 20 and the surface of the thin film 10.

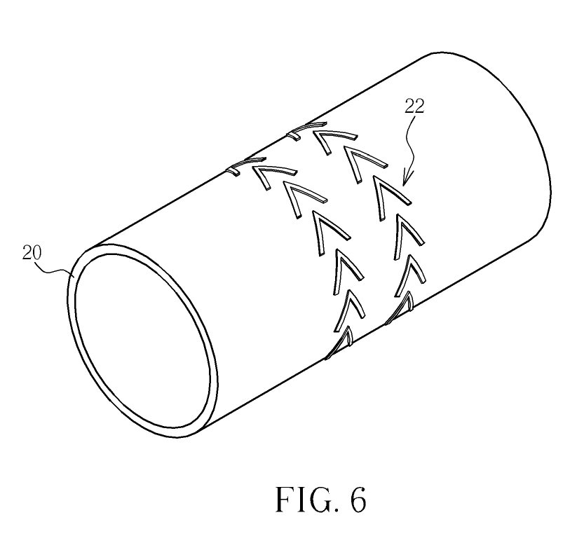

As shown in FIG. 6, a lift-off process is performed to remove the thin film 10 and the material layer 24 adhered to the thin film 20 to form a desired micro-structure on the curved surface of the element 20.

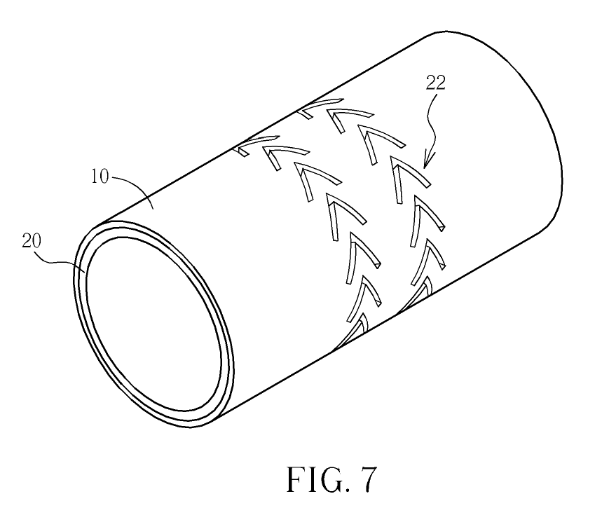

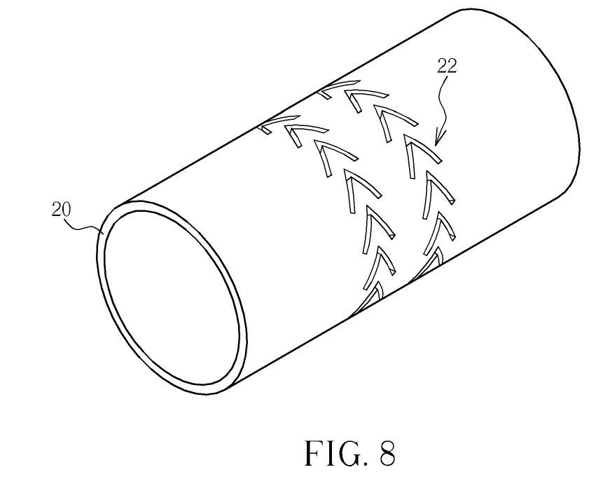

In the aforementioned embodiment, the micro-structure is formed on the non-planar curved surface of the element by thin film techniques, and the micro-structure is made of the material layer which protrudes out of the curved surface of the element. The method of the present invention is not limited by the above embodiment. Please refer to FIGS. 7 and 8. FIGS. 7 and 8 are schematic diagrams illustrating a method for treating surface of an element having a non-planar surface according to the second embodiment of the present invention. Since the front-end process of this embodiment is similar to the first embodiment, please refer to FIGS. 1-4 as well. It is appreciated that like components are designated by like numerals in these two embodiments, and repeated parts are not redundantly described. As shown in FIG. 7, the thin film 10 partially exposes the curved surface of the element 20 after developed, thereby forming the exposed region 22. Subsequently, an etching process is performed using the thin film 10 as an etching mask to remove a portion of the element 20 in the exposed region 22. The etching process may be a dry etching process or a wet etching process based on the material of the element 20 or the shape of the micro-structure to be formed.

As shown in FIG. 8, the thin film 10, which served as the etching mask, is removed to form the micro-structure on the curved surface of the element 20.

The method for treating a surface of an element of the present invention can be applied to form various types of elements having a non-planar surface such as a fluid dynamic bearing. In the aforementioned embodiments, an element having cylindrical tubal structure is used as an example and the micro-structure is formed on the outer surface (curved surface) of the cylindrical tubal element. However, the method of the present invention can also be applied to the inner surface of element and a three-dimensional element having various kinds of shapes e.g. a cylindrical structure or a cubic structure.

The present invention uses a photo-sensitive, flexible and adhesive thin film to fabricate a micro-structure on a non-planar surface of element. The thin film is exposed in advance so that a micro-structural pattern is transferred from a planar photomask to the thin film, and the thin film is attached to the non-planar surface of the element. The surface treatment is implemented by virtue of the thin film with the micro-structural pattern. Compared with the conventional method, the method of the present invention is advantageous for its high efficiency, low cost and high applicability.

Those skilled in the art will readily observe that numerous modifications and alterations of the device and method may be made while retaining the teachings of the invention.

What is claimed is:

1. A method for treating a surface of an element, comprising steps of:
providing a photo-sensitive and flexible thin film having a micro-structural pattern;
attaching the thin film having the micro-structural pattern to the surface of the element, wherein the thin film partially exposes the surface of the element so that at least an exposed region is formed on the surface of the element;
forming at least a material layer on the thin film and on the exposed region; and
removing the thin film and the material layer to form a micro-structure on the surface of the element.

2. The method of claim 1, further comprising a step of performing an exposure process to transfer the micro-structural pattern to the thin film, wherein the exposure process is carried out by a photomask having the micro-structural pattern to be disposed on the surface of the element.

3. The method of claim 1, further comprising a step of performing a developing process to partially remove the thin film so that the thin film exposes a portion of the surface of the element.

4. The method of claim 1, further comprising a step of performing a coating process to form the material layer on the thin film.

5. The method of claim 4, wherein the coating process comprises a physical vapor deposition process, a chemical vapor deposition process, an electroplating process or a non-electroplating process.

6. The method of claim 1, further comprising a step of performing a lift-off process to remove the thin film and the material layer disposed on the thin film.

7. The method of claim 1, wherein the material of the element comprises copper, glass, metal or nonmetal, and the element comprises a non-planar structure, a cylindrical tubal structure, a cylindrical structure or a three-dimensional structure.

8. The method of claim 1, wherein the thin film comprises positive type, negative type, single-layered or multi-layered photoresist.

9. The method of claim 1, wherein the material layer comprises metal, nonmetal, oxide or a mixture thereof.

10. A method for treating a surface of an element, comprising steps of:
providing a photo-sensitive and flexible thin film having a micro-structural pattern;
attaching the thin film having the micro-structural pattern to the surface of the element, wherein the thin film partially exposes the surface of the element so that at least an exposed region is formed on the surface of the element;
partially removing the element in the exposed region; and
removing the thin film to form a micro-structure on the surface of the element.

11. The method of claim 10, further comprising a step of performing an exposure process to transfer the micro-structural pattern to the thin film, wherein the exposure process is carried out by a photomask having the micro-structural pattern to be formed on the surface of the element.

12. The method of claim 10, further comprising a step of performing a developing process to partially remove the thin film so that the thin film exposes a portion of the surface of the element.

13. The method of claim 10, further comprising a step of performing an etching process to etch the element in the exposed region.

14. The method of claim 13, wherein the etching process comprises a dry etching process or a wet etching process.

15. The method of claim 10, wherein the material of the element comprises copper, glass, metal or nonmetal, and the element comprises a non-planar structure, a cylindrical tubal structure, a cylindrical structure or a three-dimensional structure.

16. The method of claim 10, wherein the thin film comprises positive type, negative type, single-layered or multi-layered photoresist.

17. A method for treating a surface of an element, comprising steps of:
providing a photo-sensitive and flexible thin film having a micro-structural pattern;
attaching the thin film having the micro-structural pattern to the surface of the element, wherein the thin film partially exposes the surface of the element so that at least an exposed region is formed on the surface of the element;
performing a surface treatment on the exposed region; and
removing the thin film to form a micro-structure on the surface of the element.

18. The method of claim 17, wherein the surface treatment comprises a coating process, a physical vapor deposition process, a chemical vapor deposition process, an electroplating process, a non-electroplating process or an etching process.

19. The method of claim 18, wherein the coating process forms a material layer on the surface of the element, and the material layer comprises metal, nonmetal, oxide or a mixture thereof.

20. The method of claim 17, wherein the thin film comprises positive type, negative type, single-layered or multi-layered photoresist.

21. The method of claim 17, wherein the element comprises a dynamic bearing.
